(19) United States
(12) Patent Application Publication
(10) Pub. No.: US 2007/0128375 A1
(43) Pub. Date: Jun. 7, 2007

(54) Method and device for continuously treating the surface of an elongate object

(76) Inventors: Stanislav Begounov, Yverdon-les-Bains (CH); Ioulia Tsvetkova, Yverdon-les-Bains (CH)

Correspondence Address: ALSTON & BIRD LLP, BANK OF AMERICA PLAZA, 101 SOUTH TRYON STREET, SUITE 4000, CHARLOTTE, NC, 28280-4000, US

(21) Appl. No.: 10/579,653

(22) PCT Filed: Nov. 18, 2003
(86) PCT No.: PCT/CH03/00763

§ 371 Date: Jan. 31, 2007

(51) Int. Cl. B08B 6/00; H05H 1/24; C23C 16/00

(52) U.S. Cl. 427/569; 118/718; 134/1.1

(57) ABSTRACT

The method and device relate to the continuous surface treatment of the surface of an elongate filamentary object by means of a plasma created by an electric discharge under ambient pressure. The device (100) comprises a tubular body (2) in which there is provided a channel (1) that is at least partially open at its two ends, for the passage of an elongate object (A) along an axis of travel substantially parallel to the longitudinal axis of the channel (1), means (3) for generating a neutral plasma flux at a set angle with respect to the longitudinal axis in at least part (10) of the body (2), and means for confining the plasma flux inside this part (10), at least while the elongate object passes through this part of the body of the channel. The device also makes it possible to vary the effect of the treatment by adding necessary additives to the plasma and/or directly into a treatment zone and by using various zones of the plasma containing particles provided with a different energy level.

### TECHNICAL FIELD

The present invention relates to a method for continuously treating the surface of an elongate object, for example a fiber, a wire or yarn, a tubular component, a ribbon, a strip or the like by means of a plasma flux created by an electrical discharge under ambient pressure, in which said elongate object is made to travel continuously through a channel provided inside a hollow tubular body, that is at least partially open at its two ends, along an axis of travel substantially parallel to the longitudinal axis of said channel.

It also relates to a device for continuously treating the surface of an elongate object, for example a fiber, a wire or yarn, a tubular component, a ribbon, a strip or the like by means of a plasma flux created by an electrical discharge under ambient pressure, in which said elongate object is made to pass continuously through a channel provided inside a hollow tubular body, that is at least partially open at its two ends, along an axis of travel substantially parallel to the longitudinal axis of said channel, in order to implement the method of the invention.

The invention finally relates to a use of the method for modifying the physical properties of the surface of a filamentary object.

### PRIOR ART

Surface treatments performed successively or simultaneously may for example encompass cleaning, scouring, surface activation, deposition of a film, or any treatment enabling the physical properties of a surface to be modified and in particular a surface of an elongate object made of insulating or conducting material, or a textile material with natural or synthetic fibers.

The elongate objects to be treated comprise all types of yarn, made of natural or synthetic material, yarns consisting of blended or intermingled fibers or filaments and yarns consisting of braided fibers for textile or technical use.

U.S. Pat. No. 4,397,893 describes a method for treating the surface of a metal rod such as a piston rod, in which a plasma torch directed towards the rod and positioned perpendicularly thereto is moved along this rod while it is rotated about its axis. This device requires synchronized movement of a preheating device, of the plasma torch and of the rod support. The low speed at which this method is carried out in the longitudinal direction of the rod coupled with the necessity of rotating the latter about its axis, makes this method incompatible with most industrial production lines for wires or yarns and similar products.

### DESCRIPTION OF THE INVENTION

A first object of the present invention is to provide a method as well as a device for treating the surface of an elongate object producing a homogeneous result, in a single operation on all sides of this elongate object, enabling various types of plasma and additives to be used with the object of being able to carry out various chemical and physical treatments by using plasma and that can be applied to optical fibers as well as threads, metal cables or cords.

A second object of the present invention is to provide a method and a device of the aforesaid type which is incorporated in a production line while modifying as little as possible the construction and parameters of this line, while guaranteeing a high degree of safety during its use.

These objects are achieved by means of the method as defined in the preamble and in which a neutral plasma flux is generated by means of an electrical discharge generated by a voltage applied between a central electrode and ground, said neutral plasma flux being generated at a set angle with respect to said longitudinal axis in at least part of said body of the channel and in which said plasma flux is substantially confined inside said part of said body of the channel, at least while said elongate object passes through this part of the body of the channel.

According to a preferred embodiment, said plasma flux makes an acute angle with respect to said axis of travel of said elongate object.

Advantageously, at least said part of said body of the channel is put into fluid communication with the outside atmosphere.

Said electrical discharge is chosen in a suitable manner according to the applications and is generated by an electric voltage chosen from the group of voltages consisting of direct, pulsed or alternating voltages with any frequency ranges.

According to a particularly efficient way of proceeding, said plasma flux is generated by means of a supply duct connected to the channel in said part of said body of this channel.

In order to perform specific treatments, said plasma is maintained by at least one carrier fluid injected into a device generating said plasma. Said plasma is preferably maintained by means of a carrier fluid that contains a treatment component in an injectable form. Said injectable form may be a gas, a vapor, a mixture of gas and vapor, or a compound comprising a fluid vehicle containing gaseous or solid particles or a mixture of these particles.

According to a particularly advantageous variant, several plasma fluxes are generated at set angles with respect to the longitudinal axis of said body of the channel, and said plasma fluxes are substantially confined respectively in said parts of said body of the channel and said plasma fluxes are maintained respectively with specific carrier fluids.

According to the application, the elongate object may be made to move in said channel at a speed extending from a few centimeters/second to several tens of meters/second.

These objectives are also achieved by means of the device defined in the preamble and which comprises means for generating a neutral plasma flux by means of an electrical discharge generated by a voltage applied between a central electrode and ground, means for generating said neutral plasma flux at a set angle with respect to said longitudinal axis in at least part of said body of the channel and means for substantially confining said plasma flux inside said part of said body of the channel at least while said elongate object passes through this part of the body of the channel.

According to a preferred mode of construction, said means for generating a plasma flux at a set angle with respect to the longitudinal axis of said body of the channel comprise a plasma-generating device provided with a supply duct connected to said channel in said part of said body of this channel, this supply duct forming an angle with the axis of travel of the elongate object.

The plasma-generating device is preferably arranged so as to produce the plasma flux with the aid of an electrical discharge made between an electrode and said part of the body of the channel, this plasma flux being substantially confined between the inner walls of this part of the body of said channel.

The supply duct advantageously forms an angle with the axis of travel of the elongate object of between 0 and 90 degrees and preferably between 30 and 60 degrees.

According to a first mode of construction, the channel is provided in a tubular body made of a material resistant to the temperature of the plasma flux.

According to a second mode of construction, the channel is provided in a tubular body made of a material having good thermal conductivity and the outer wall of the body of the channel is cooled. Among materials that can be used, mention may be made of quartz or ceramics, in particular ceramics based on alumina, having good thermal conductivity.

The plasma flux may be generated in a laminar manner so as to attain a speed of propagation of the plasma equal to or greater than that of the passage of the elongate object.

The device advantageously includes means for making said elongate object move at a speed extending from a few centimeters/second to several tens of meters/second. Preferably, the same speed of movement is adopted as the work stations upstream and/or downstream to the plant for producing or converting the elongate object.

This device may advantageously include two plasma-generating devices oriented so as to direct the plasma fluxes in opposite directions.

For some applications, said body of the channel includes separating means arranged so as to cut off the interior of said channel from the outside atmosphere.

It is also possible to associate the supply duct of the plasma generator with a duct for injecting the carrier fluid.

According to a particularly advantageous variant, said channel comprises several parts as well as several plasma-generating devices arranged so as to generate several plasma fluxes at set angles with respect to the longitudinal axis of said body of the channel, said plasma fluxes being respectively confined in said parts of said body of the channel and each of said respective plasma fluxes being maintained with specific carrier fluids. As a nonlimiting example of a carrier fluid, mention may be made of argon, air or nitrogen. The carrier fluid may convey a plasmo-chemical treatment component, such as oxygen, carbon tetrafluoride, carbon tetrachloride or the like.

The channel may, if necessary, be subjected to a partial vacuum, by means of a pump, or be placed in a vacuum chamber or in a controlled atmosphere.

### BRIEF DESCRIPTION OF THE DRAWINGS

Other features of the method and of the device according to the invention will become apparent from the description below, showing several methods for constructing the device as well as examples of applications of the method, with reference to the appended drawings in which:

FIG. 1 is a diagrammatic view in longitudinal section of a first embodiment of the treatment device according to the invention,

FIG. 2 shows a diagrammatic view in longitudinal section of a second embodiment of the treatment device according to the invention,

FIG. 3 shows a diagrammatic view in longitudinal section of a third embodiment of the treatment device according to the invention,

FIG. 4 shows a diagrammatic view in longitudinal section of a fourth embodiment of the treatment device according to the invention, and

FIG. 5 shows a diagrammatic view in longitudinal section of a fifth embodiment of the treatment device according to the invention.

### BEST WAYS OF IMPLEMENTING THE INVENTION

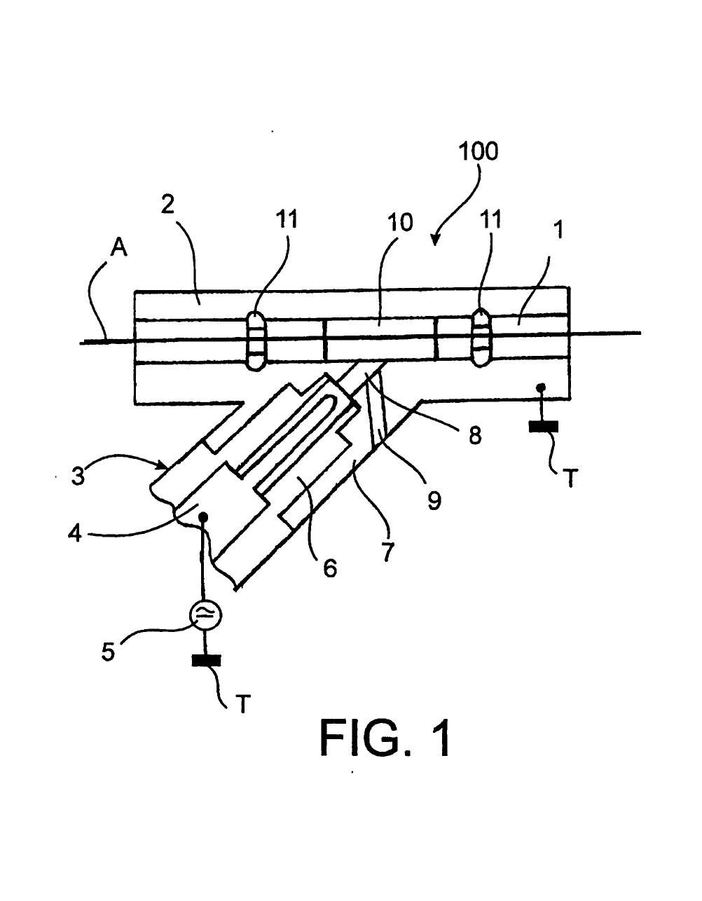

With reference to FIG. 1, the device 100 comprises a channel 1 provided inside a hollow cylindrical body 2, open at its two ends, made for example of copper or of an insulating or even refractory material. This cylindrical body 2 is electrically connected to a ground T and is fitted with means for generating a neutral plasma flux in the channel 1 by means of an electrical discharge generated by a voltage applied between a central electrode and the ground T, so that the channel 1 is not traversed by any electrical voltage. To this end, the body 2 is connected to a plasma-generating device 3 comprising an electrode 4 connected to an electric power source 5, itself connected to the ground T. The electrode 4 of the plasma-generating device 3 is housed inside an insulator 6 itself mounted in an end-piece 7 connected to the channel 1. This end-piece 7 is preferably positioned so that its longitudinal axis forms an acute angle, for example between 30 and 60 degrees, with the axis of the channel 1 which is in fact the axis of travel of an elongate object A to be treated, partially represented and positioned along the axis of the channel 1. The electric power source 5 may be a direct voltage generator or an alternating voltage generator. The plasma-generating device 3 is connected to the channel 1 via a supply duct 8 of which the axis is inclined with respect to the axis of the channel 1. A duct 9 for injecting a carrier fluid which may be a treatment gas or a vapor or a carrier fluid charged with solid particles etc, emerges in this supply duct 8.

The portion of the elongate object A passing through the channel 1 is held in a substantially central position with the aid of guides 11 incorporated in the channel, as well as with the aid of tensioning devices and drive devices outside said channel (not shown), such as those used in the textile industry for causing a yarn to pass through a succession of treatment stations, that are positioned outside the channel 1 and enable a portion of the elongate object A, for example a yarn, to be held, tightened and provided with a movement in the longitudinal direction of the channel. Movement may occur in the right-left direction or in the left-right direction according to the type of treatment to be applied.

The plasma-generating device 3 generates a neutral plasma flux that is transmitted through the supply duct 8 and which is then localized in a part 10 of the channel in which the plasma is confined. On account of this, the portion of the elongate object A, of which the surface is to be treated, is entirely immersed in the plasma as it passes within the channel 1. The substance that may be necessary for treatment can be added to the plasma either by direct injection or by means of a carrier fluid through the injection duct 9. This substance is chosen according to the treatment carried out, namely cleaning, scouring or surface deposition.

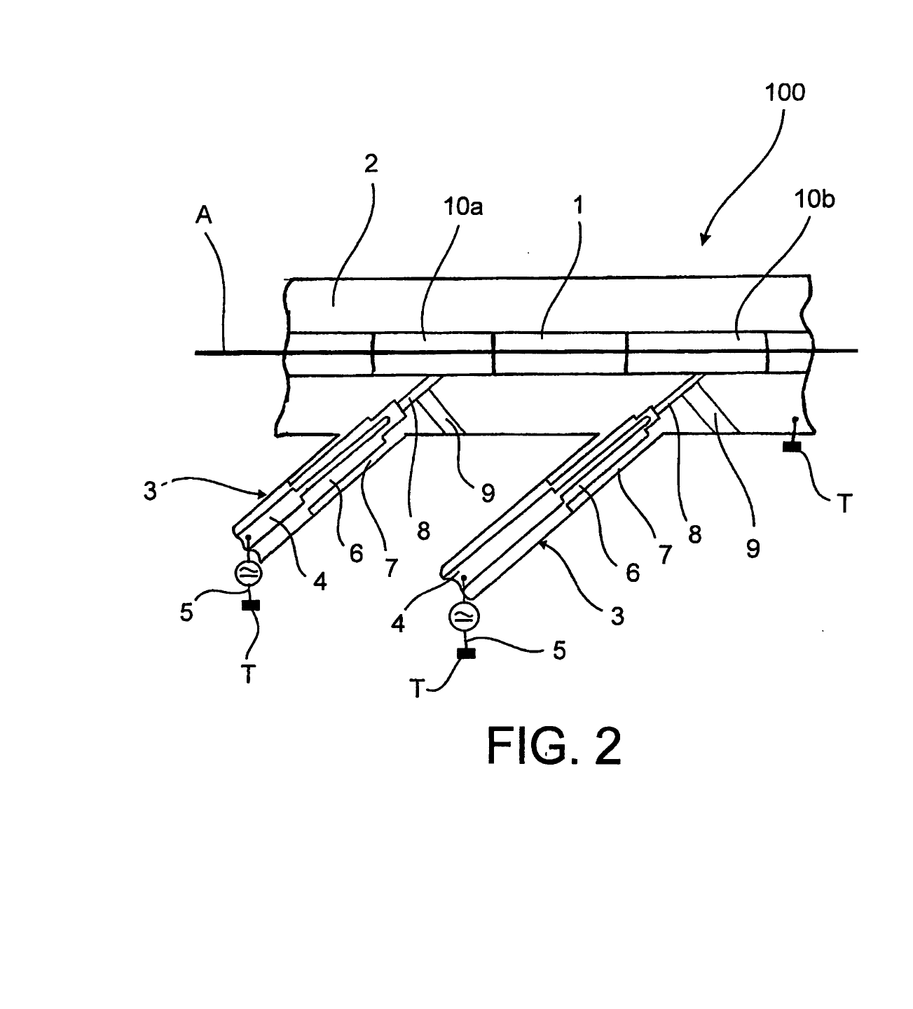

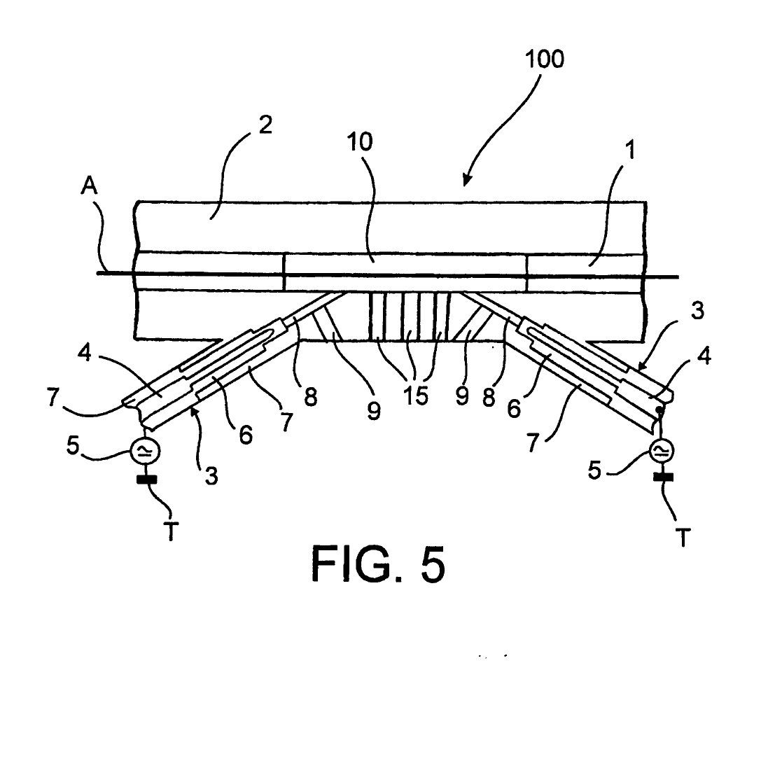

FIG. 2 is a longitudinal section of a second embodiment of the treatment device according to the invention. The channel 1 comprises in particular two parts 10a and 10b inside which the plasma is confined and each of which is associated with its own plasma-generating device 3 identical to that described with reference to FIG. 1. Assuming that the electrical power sources 5 associated respectively with the two generating devices are identical to the electrical power source 5 of the device of FIG. 5 and that they provide the same voltage, and assuming that the elongate object A passes inside the channel 1 at the same speed, this device makes it possible, under identical treatment conditions, to double the contact time between this object and the plasma or, conversely, with an equal contact time between the object and the plasma, this device makes it possible to double the speed with which the object moves.

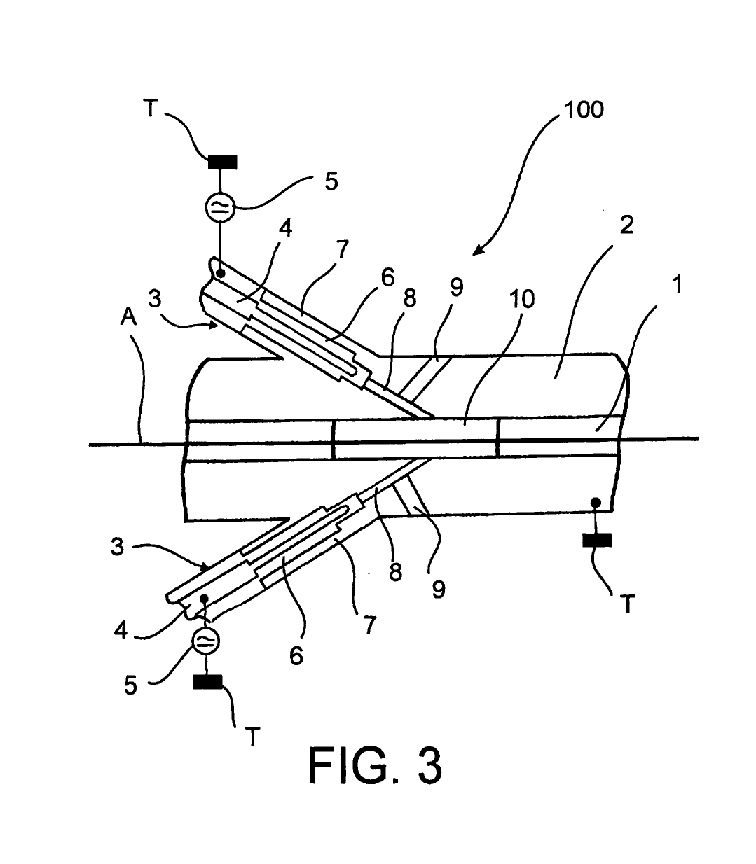

FIG. 3 is a view in longitudinal section of a third embodiment of the treatment device according to the invention. The channel 1 is provided with two plasma-generating devices 3, orientated so as to fill with plasma a part 10 of the channel in which the plasma is confined with the aim of increasing the plasma density and therefore of enabling the treatment speed to be increased while increasing the speed of passage of the elongate object A. This embodiment also makes possible a treatment which requires the use of substances that cannot be mixed directly before being injected into the plasma, which must be necessarily present at the same time on a surface of the elongate object in order for the treatment to succeed. In this case, these substances are injected into the plasma via the injection ducts 9. The plasma-generating devices 3 are associated with two electrical energy sources 5 which deliver electric voltages that may be identical or different according to the application.

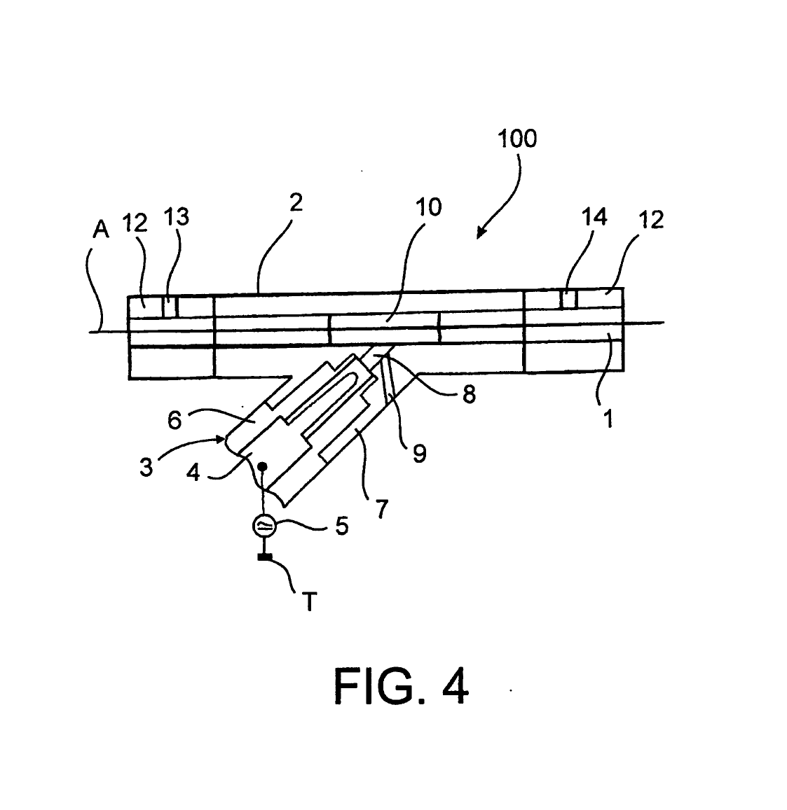

FIG. 4 is a view in longitudinal section of a fourth embodiment of the treatment device 100 according to the invention. In this variant, the channel 1 is equipped at the ends with separating devices 12 intended to isolate a part 10 in which the plasma is confined from the ambient atmosphere. These separating devices represent types of buffer volumes which may be put under excess pressure or under vacuum through the openings 13 and 14. They are provided for example in order to isolate the elongate object A passing through said channel 1 from the rest of the external atmosphere in relation to that inside the channel 1 and the part 10 which is the treatment zone. This arrangement also makes it possible to graft molecules of a substance onto the surface of the elongate object or to carry out two operations consecutively if two separating devices are installed in series.

FIG. 5 represents a longitudinal section of a fifth embodiment of the treatment device 100 according to the invention. The treatment zone, consisting of the part 10 in which the plasma is confined, is filled with plasma created by two plasma-generating devices 3 positioned so as to direct the plasma at a set angle with respect to the channel 1 in directions of propagation of the plasma opposed to each other, which enables the treatment zone to be widened. In order to bring the substances that are necessary for the treatment towards this treatment zone, injection ducts 9 previously described may be used. Other complementary injection ducts 15, making it possible to deliver the substances necessary for treatment directly into the treatment zone or to use substances that are too sensitive to the plasma medium and which could, in the case of a standard process for injection into the plasma, be destroyed before they can produce the expected effects on a surface of the elongate object to be treated.

The voltages delivered by the power sources 5 may all be different or identical according to the application.

The treatment device according to the invention may be the subject of many other modifications without departing from the scope of the invention. In particular, in order to facilitate construction, the body 2 may be made in two elements capable of being separated and that are, in the longitudinal direction, in the form of an open trough and of a cover with a complementary shape and dimensions, so as to define, between them, the channel for the passage of the object to be treated.

The method and device according to the invention make it possible to treat various elongate objects, in particular filamentary objects, with a very low plasma volume. This small volume leads to a very low electrical power and treatment gas consumption for the creation of the plasma. Moreover, since the device is connected to ground, it may be used for the treatment of metal wires, and in particular conducting wires, in complete safety.

A few uses for the device of the invention for the treatment of an elongate object will be described below by way of examples.

### Example 1

This example shows the use of the device used in its first mode for carrying out a treatment by surface burning of cotton yarn.

Parameters of the method

| Power | AC (20 kHz) | |
|---|---|---|
| Electric voltage applied to the plasma | 500 | V |
| Carrier/treatment gas | Air | |
| Flow rate of carrier/treatment gas | 2 | l/min |
| Speed of passage of the yarn | 10 | m/sec |

Result—the treatment is more than three times more efficient than the standard method using a flame.

### Example 2

This example uses the device according to the invention in its first embodiment for carrying out scouring of part of the surface of a synthetic yarn.

Parameters of the method

| Power | DC | |
|---|---|---|
| Electric voltage applied to the plasma | 800 | V |
| Carrier gas | Nitrogen | |
| Treatment gas | Oxygen | |
| Flow rate of carrier gas | 2.5 | l/min |
| Flow rate of treatment gas | 1 | l/min |
| Speed of passage of the yarn | 10 | m/sec |

Result—The treatment made it possible to remove 10% of the total weight of the synthetic yarn by creating crazing on its surface.

### Example 3

This example uses the device in its first embodiment for depositing a layer of SiOX on the surface of a synthetic yarn.

Parameters of the method:

| Power | AC (13.56 MHz) | |
|---|---|---|
| Carrier gas | Argon | |
| Treatment gas | Oxygen + C₉H₁₉NSi₂ | |
| | (vapor) | |
| Flow rate of carrier gas | 2 | l/min |
| Flow rate of treatment gas | 0.2 | l/min |
| Speed of passage of the yarn | 5 | m/sec |

Result—the treatment made it possible to obtain a layer of SiOₓ (x=1.8-2.2) having a thickness of approximately 0.1 microns.

1. A method for continuously treating the surface of an elongate object, for example a fiber, a wire or yarn, a tubular component, a ribbon, a strip or the like by means of a plasma flux created by an electrical discharge under ambient pressure, in which said elongate object is made to travel continuously through a channel provided inside a hollow tubular body, that is at least partially open at its two ends, along an axis of travel substantially parallel to the longitudinal axis of said channel, in which, in this method, a neutral plasma flux is generated by means of an electrical discharge generated by a voltage applied between a central electrode and ground, said neutral plasma flux being generated at a set angle with respect to said longitudinal axis in at least part of said body of the channel and in which said plasma flux is substantially confined inside this part of said body of the channel, at least while said elongate object passes through this part of the body of the channel.

2. The method as claimed in claim 1, in which said plasma flux forms an acute angle with respect to said axis of travel of said elongate object (A).

3. The method as claimed in claim 1, in which at least said part (10) of said body (2) of the channel (1) is put into fluid communication with the outside atmosphere.

4. The method as claimed in claim 1, in which said electrical discharge is generated by an electric voltage chosen from the group of voltages consisting of direct, pulsed or alternating voltages with any frequency ranges.

5. The method as claimed in claim 1, in which said plasma flux is generated by means of a supply duct (8) connected to said part of said body of this channel.

6. The method as claimed in claim 1, in which said plasma is maintained by at least one carrier fluid injected into a device generating said plasma.

7. The method as claimed in claim 6, in which said plasma is maintained by means of a carrier fluid that contains a plasmo-chemical treatment component in an injectable form.

8. The method as claimed in claim 7, in which said injectable form is a gas, a vapor, a mixture of gas and vapor, or a compound comprising a fluid vehicle containing gaseous or solid particles or a mixture of these particles.

9. The method as claimed in claim 1, in which several parts of the body of the channel are defined, in which several plasma fluxes are generated at set angles with respect to the longitudinal axis of this body of the channel, in which said plasma fluxes are substantially confined respectively inside said parts of said body of the channel, and in which said plasma fluxes are maintained respectively with specific carrier fluids.

10. The method as claimed in claim 1, in which the elongate object (A) is made to move in said channel (1) at a speed extending from a few centimeters/second to several tens of meters/second.

11. A device for continuously treating the surface of an elongate object, for example a fiber, a wire or yarn, a tubular component, a ribbon, a strip or the like by means of a plasma flux created by an electrical discharge under ambient pressure, comprising a channel (1) provided inside a hollow tubular body, that is at least partially open at its two ends, arranged so as to allow said elongate object (A) to pass along an axis of travel substantially parallel to the longitudinal axis of said channel, in order to implement the method of any one of claims 1 to 10, in which this device (100) comprises means for generating a neutral plasma flux by means of an electrical discharge generated by a voltage applied between a central electrode and ground, means for generating said neutral plasma flux at a set angle with respect to said longitudinal axis in at least part of said body of the channel (1), and means for confining substantially said plasma flux inside this part (10) of said body of the channel, at least while said elongate object (A) passes through this part of the body of the channel.

12. The device as claimed in claim 11, in which said means for generating a plasma flux at a set angle with respect to the longitudinal axis of said body of the channel comprise a plasma-generating device (3) provided with a supply duct (8) connected to said channel (1) in said part (10) of said body of this channel, this supply duct forming an angle with the axis of travel of the elongate object (A).

13. The device as claimed in claim 12, in which the plasma-generating device (3) is arranged so as to produce the plasma flux with the aid of an electrical discharge made between an electrode (4) and said part (10) of the body (2) of the channel (1), this plasma flux being substantially confined between the inner walls of this part (10) of the body of said channel.

14. The device as claimed in claim 12, in which the supply duct (8) of the plasma-generating device (3) makes an angle with the axis of travel of the elongate object (A) of between 0 and 90 degrees and preferably between 30 and 60 degrees.

15. The device as claimed in claim 11, in which the channel (1) is provided in a tubular body (2) made of a material resistant to the temperature of the plasma flux.

16. The device as claimed in claim 11, in which the channel (1) is provided in a tubular body (2) made of a material having good thermal conductivity, and in which the outer wall of said channel (1) is cooled.

17. The device as claimed in claim 11, in which the plasma flux is generated in a laminar manner and so as to attain a speed of propagation of the plasma equal to or greater than that of the travel of the elongate object (A).

18. The device as claimed in claim 11, which includes means for making said elongate object (A) move at a speed extending from a few centimeters/second to several tens of meters/second.

19. The device as claimed in claim 11, which comprises two plasma-generating devices (3) oriented so as to direct the plasma fluxes in opposite directions.

20. The device as claimed in claim 11, in which said channel (1) includes separating means (12) arranged so as to cut off the interior of said channel (1) from the outside atmosphere.

21. The device as claimed in claim 12, in which said supply duct (8) of the plasma generator (3) is associated with a duct (9) for injecting carrier fluid.

22. The device as claimed in claim 11, in which said channel (1) comprises several parts (10a, 10b), as well as several plasma-generating devices (3) arranged so as to generate several plasma fluxes at set angles with respect to the longitudinal axis of said body of the channel, said plasma fluxes being confined respectively inside said parts (10a, 10b) of said body of the channel and each of said respective plasma fluxes being maintained with specific carrier fluids.

23. The device as claimed in claim 11, in which said channel (1) comprises means (13, 14, 15) for enabling it to be subjected to a partial vacuum or to a controlled atmosphere.

24. The use of the method as claimed in claim 1 modifying the physical properties of the surface of a filamentary object.
